(19) United States
(12) Patent Application Publication
(10) Pub. No.: US 2025/0192509 A1
(43) Pub. Date: Jun. 12, 2025

(54) OPTICAL CHIP PACKAGING MODULE, OPTICAL MODULE AND LiDAR

(71) Applicant: SUTENG INNOVATION TECHNOLOGY CO., LTD., Shenzhen (CN)

(72) Inventors: Penghui WANG, Shenzhen (CN); Wei XU, Shenzhen (CN)

(73) Assignee: SUTENG INNOVATION TECHNOLOGY CO., LTD., Shenzhen (CN)

(21) Appl. No.: 18/946,893

(22) Filed: Nov. 13, 2024

(30) Foreign Application Priority Data
Dec. 6, 2023 (CN) 202311673973.7

(51) Int. Cl. H01S 5/026; H01S 5/02345; H01S 5/042; H01S 5/42

(52) U.S. Cl. CPC H01S 5/0261; H01S 5/02345; H01S 5/04256; H01S 5/423

(57) ABSTRACT

An optical chip packaging module, an optical module, and a LiDAR are provided. The optical chip packaging module includes: a substrate provided with an optical region and a non-optical region; an optical chip fixed in the optical region of the substrate; a barrier member fixed on the substrate for isolating the optical region from the non-optical region, so as to separate the optical chip in the optical region from a device in the non-optical region; and a light-transmitting area located above the optical region, from which an outgoing light beam of the optical chip is emitted.

### CROSS-REFERENCE TO RELATED APPLICATION

The present application claims the benefit of priority to Chinese Patent Application No. 202311673973.7, filed on Dec. 6, 2023, which is hereby incorporated by reference in its entirety.

### TECHNICAL FIELD

The present application pertains to the field of packaging technology, and more specifically, to an optical chip packaging module, an optical module, and a LiDAR.

### BACKGROUND

In the field of autonomous driving and intelligent perception, LiDAR is one of the key components. Its working principle is to emit light beams to a target, then receive the echo light beams reflected from the target and perform information comparison processing to obtain relevant information about the target, such as target distance, direction, speed, and other parameters. LiDAR includes an emitter, a receiver, and a signal processing unit, in which both the emitter and the receiver need to have a light-transmitting structure, which makes the packaging of LiDAR chips different from traditional integrated circuit packaging.

In order to meet the packaging protection and light transmission requirements of the LiDAR chip, as well as the size limit of the LiDAR chip, various chips and devices need to be integrated on the same carrier board for interconnection and unified packaging, which makes it difficult to distinguish between the two types of chips during the packaging process.

### SUMMARY

Embodiments of this application provide an optical chip packaging solution, an optical module, and a LiDAR. The optical chip packaging solution is suitable for emitting/receiving modules and a LiDAR, which can improve the strength of the optical chip packaging structure and reduce the packaging cost.

In a first aspect, embodiments of the present application provide an optical chip packaging module, including: a substrate which is provided with an optical region and a non-optical region; an optical chip which is fixed to the optical region of the substrate; a barrier member which is fixed on the substrate and is used to separate the optical region from the non-optical region, so as to separate the optical chip in the optical region from a device in the non-optical region; a light-transmitting area which is located above the optical region, and an outgoing light beam of the optical chip is emitted from the light-transmitting area.

In some embodiments, the optical chip includes at least one group of lasers or receivers; and the device located on the non-optical region includes an energy storage capacitor, and a driving module for driving at least part of the at least one group of lasers to emit the light beam through energy in the energy storage capacitor.

In some embodiments, the optical chip includes at least two groups of vertical-cavity surface-emitting lasers; the driving module includes at least a first low-side driver chip and at least a first high-side driver chip; the first high-side driver chip and the first low-side driver chip drive the at least one group of the at least two groups of vertical-cavity surface-emitting lasers to emit light beams, by selecting the at least one group of the selected vertical-cavity surface-emitting lasers.

In some embodiments, the at least two groups of vertical-cavity surface-emitting lasers are vertical-cavity surface-emitting laser array; the driving module further includes a second high-side driver chip, where the first high-side driver chip and the second high-side driver chip are respectively located on two opposite sides of the vertical-cavity surface-emitting laser array, and are respectively used to drive different groups of vertical-cavity surface-emitting lasers in the vertical-cavity surface-emitting laser array; and/or, the driving module also includes a second low-side driver chip. The first low-side driver chip and the second low-side driver chip are respectively located on opposite sides of the vertical-cavity surface-emitting laser array, and are respectively used to drive different groups of vertical-cavity surface-emitting lasers in the vertical-cavity surface-emitting laser array.

In some embodiments, the device located on the non-optical region further includes at least one bootstrap capacitor for turning on or maintaining a driving state of the first high-side driver chip; and/or, a device located on the non-optical region also includes at least one decoupling capacitor corresponding to the first high-side driver chip and/or the first low-side driver chip, and the first high-side driver chip and/or the first low-side driver chip are connected to the ground through the corresponding decoupling capacitor.

In some embodiments, the thermal expansion coefficient of the barrier member and the thermal expansion coefficient of the substrate are both within [8×10⁻⁶/deg, 12×10⁻⁶/deg].

In some embodiments, a limit groove is provided on the substrate for cooperating with a protrusion at the bottom of the barrier member to fix the barrier member; and/or, a limit groove is arranged at the bottom of the barrier member, which is used to cooperate with the protrusion on the base plate to fix the barrier member.

In some embodiments, a light-transmitting cover plate is further arranged on the substrate; the barrier member is further used to support the light-transmitting cover plate, and the light-transmitting cover plate and the barrier member are enclosed on the substrate to form a sealed cavity; the optical chip is located in the sealed cavity.

In some embodiments, a limiting step cooperating with the light-transmitting cover plate is provided on the top of the barrier member, and is used to match with the periphery of the light-transmitting cover plate, to limit the light-transmitting cover plate.

In some embodiments, the substrate is made of a thermally conductive material; or, a heat conduction channel is provided on the substrate in the optical region, and the optical chip is mounted on the heat conduction channel.

In some embodiments, a plastic packaging material is provided on at least part of the non-optical region on the substrate, to reinforce the optical chip packaging module. In some embodiments, the plastic packaging material is used to seal the device located on the non-optical region.

In some embodiments, the plastic packaging material extends onto the periphery of the light-transmitting cover plate, to press the light-transmitting cover plate toward the top of the barrier member.

In some embodiments, the periphery of the light-transmitting cover plate has a slope structure or a step structure, and the plastic packaging material extends onto the slope structure or the step structure.

In some embodiments, the periphery of the light-transmitting cover plate extends to cover at least a portion of the plastic packaging material and is fixed to the plastic packaging material by adhesive; or, the periphery of the light-transmitting cover plate extends to abut against a side surface of the plastic packaging material.

In some embodiments, the thermal expansion coefficient of the plastic packaging material is within [11×10⁻⁶/deg, 14×10⁻⁶/deg].

In some embodiments, the thermal expansion coefficient of the plastic packaging material is higher than the thermal expansion coefficient of the substrate or the barrier member.

In a second aspect, embodiments of the present application provide an emitting module, including the optical chip packaging module and a circuit board; the circuit board is provided with a power supply and a charging circuit; the circuit board is electrically connected to the optical chip packaging module.

In a third aspect, embodiments of the present application provide a LiDAR, including the optical chip packaging module.

In some embodiments, a barrier member is provided on the substrate to divide the optical region and the non-optical region, so that the optical chip in the optical region and the device in the non-optical region can be effectively separated and the two regions can be packaged and protected. In addition, the provision of the barrier member can make it unnecessary to perform special differentiation and protection on the optical chip located in the optical region during the molding of the plastic packaging material and the subsequent packaging process in the optical chip packaging module, thereby reducing the steps of the packaging process, improving the chip structure strength, and reducing the material cost, fixture cost and packaging process cost.

### BRIEF DESCRIPTION OF DRA WINGS

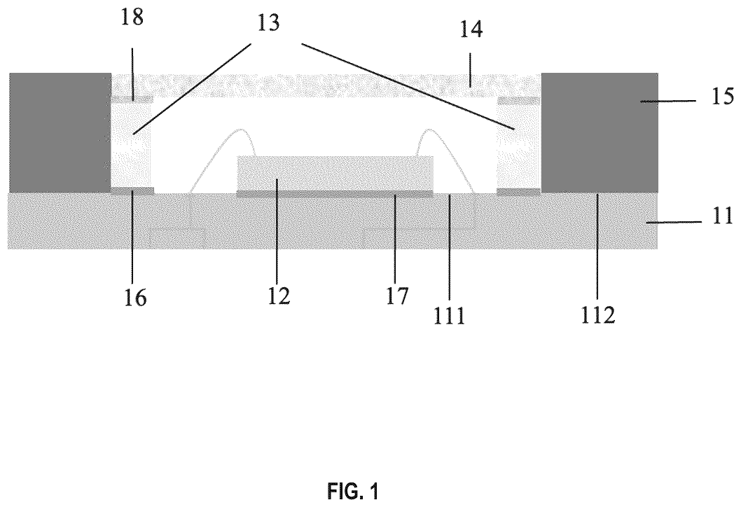

FIG. 1 is a schematic diagram of an embodiment of an optical chip packaging module;

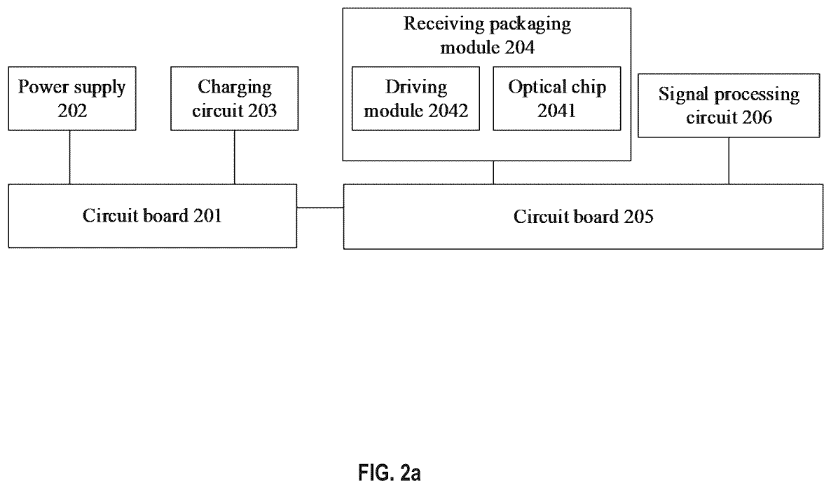

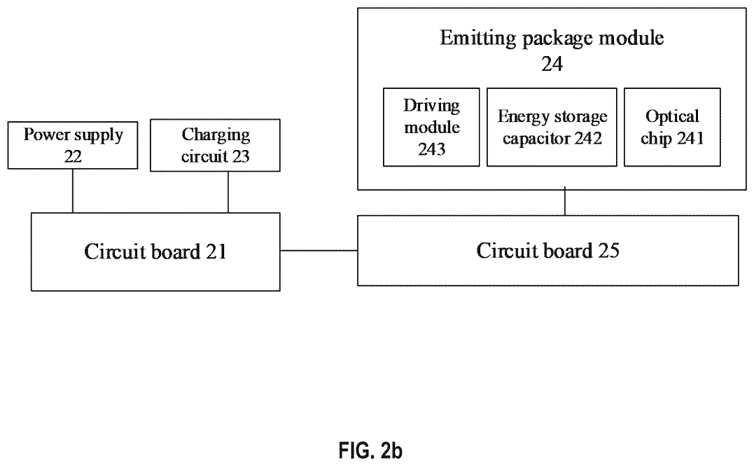

FIG. 2a is a schematic diagram of the logical structure of an embodiment of a receiving module;

FIG. 2b is a schematic diagram of the logical structure of an embodiment of an emitting module;

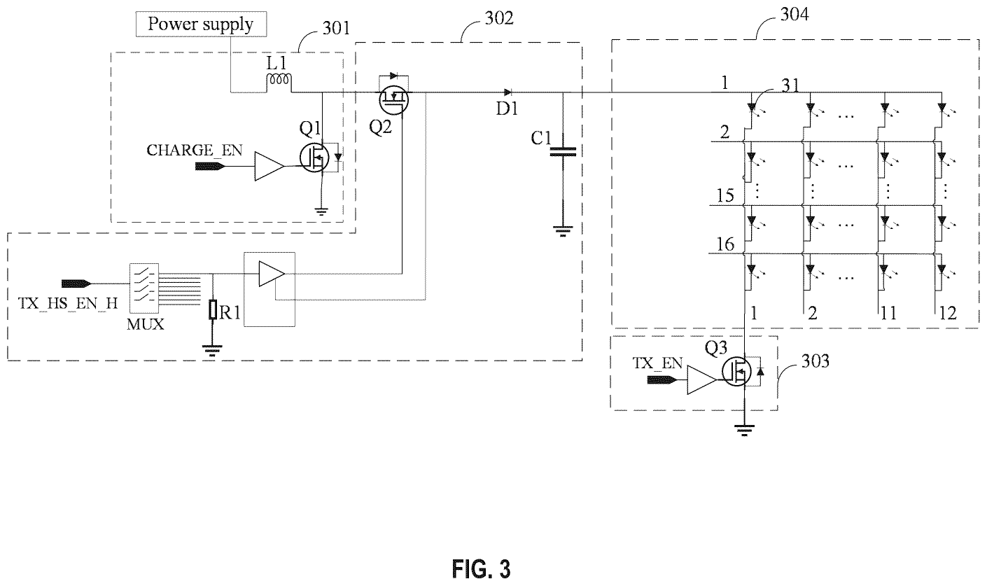

FIG. 3 is a schematic diagram of a circuit topology structure of an embodiment of an emitting module;

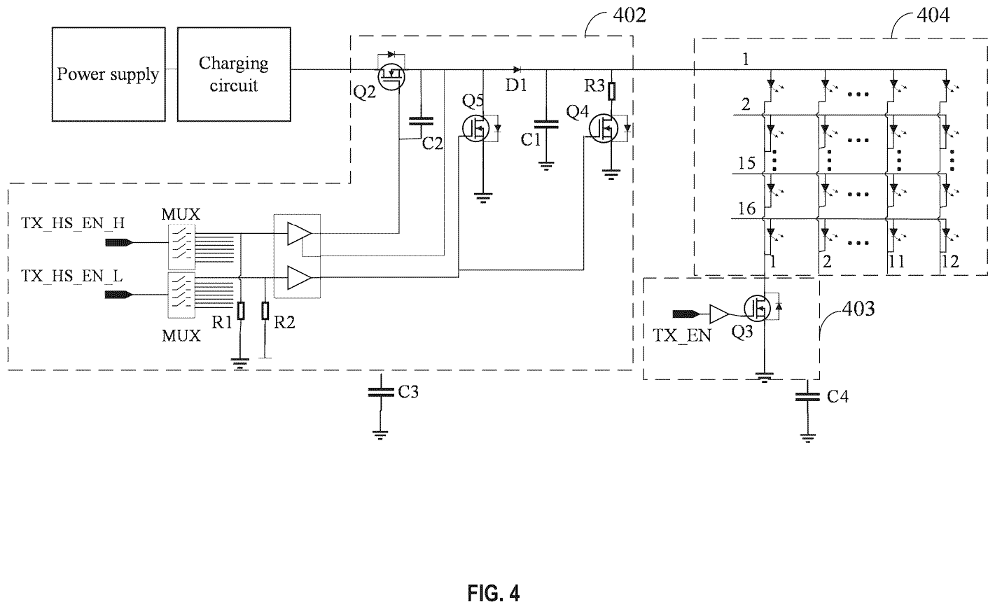

FIG. 4 is a schematic diagram of a circuit topology structure of another embodiment of an emitting packaging module;

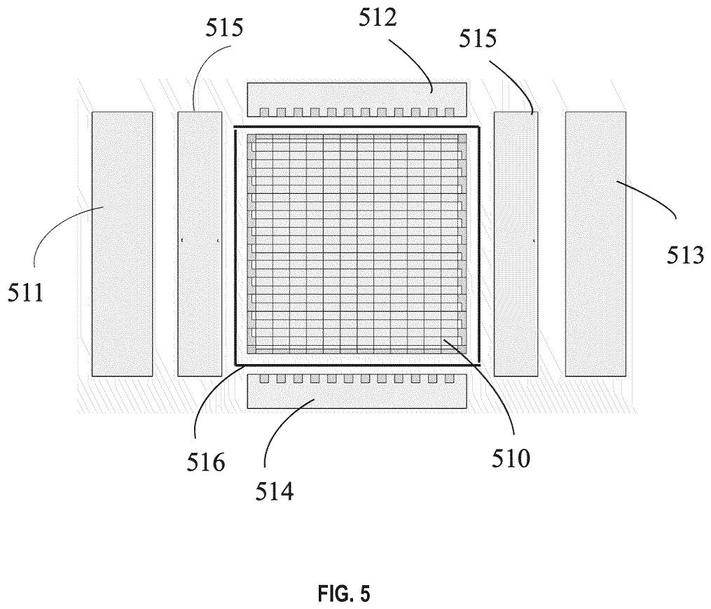

FIG. 5 is a schematic diagram of an embodiment of an arrangement of at least some components in an emitting package module;

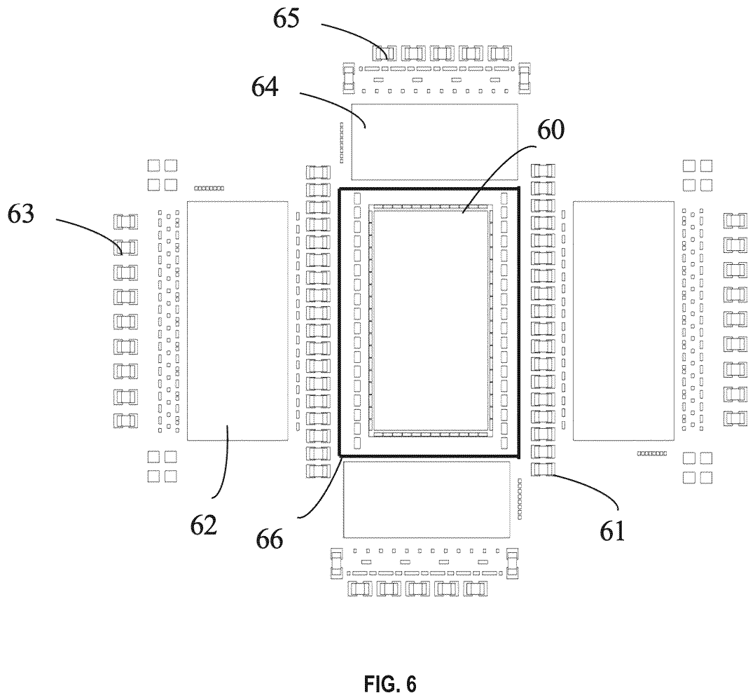

FIG. 6 is a schematic diagram of an embodiment of an arrangement of at least some components in an emitting package module group;

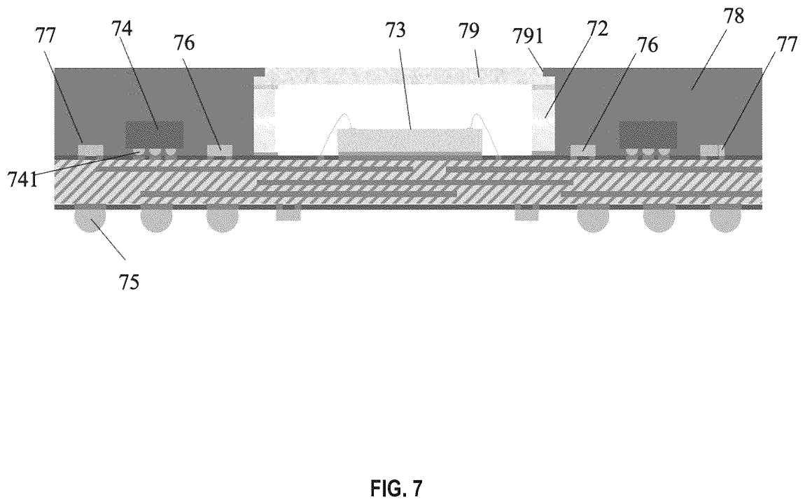

FIG. 7 is a cross-sectional schematic diagram of a partial structure of an embodiment of an optical chip packaging module;

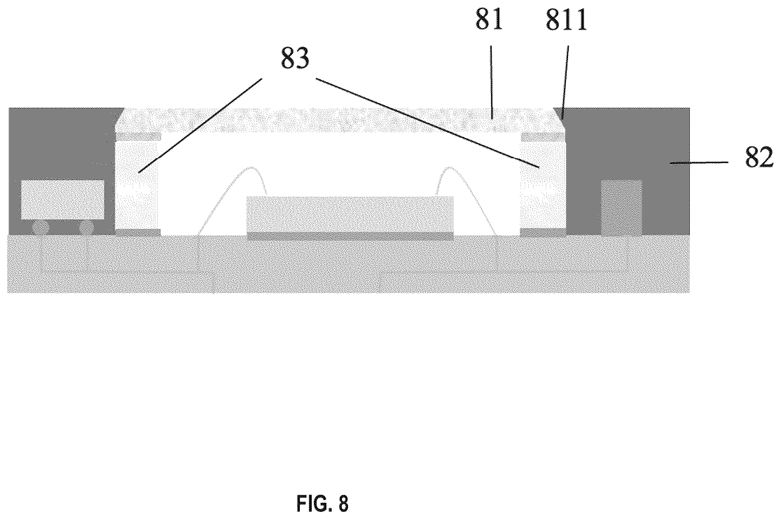

FIG. 8 is a cross-sectional schematic diagram of a partial structure of an embodiment of an optical chip packaging module;

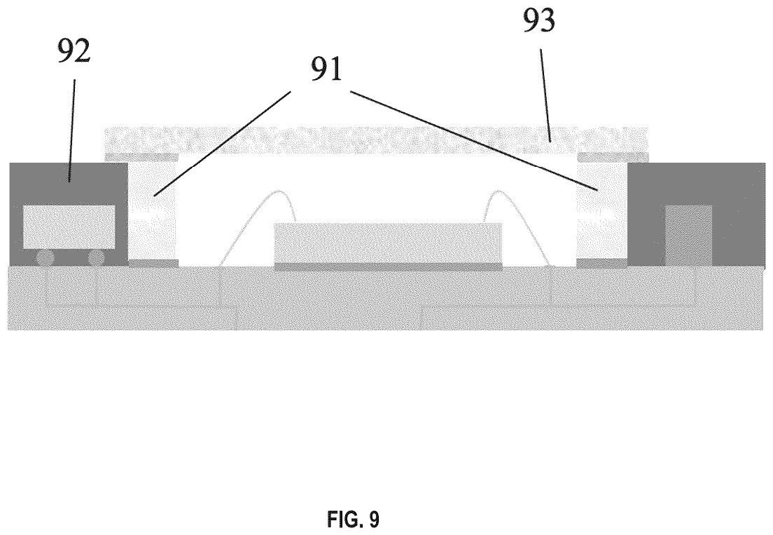

FIG. 9 is a cross-sectional schematic diagram of a partial structure of an embodiment of an optical chip packaging module;

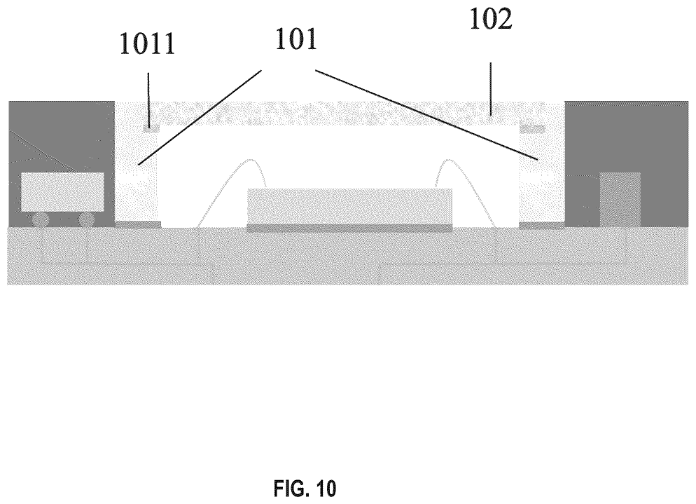

FIG. 10 is a cross-sectional schematic diagram of a partial structure of an embodiment of an optical chip packaging module;

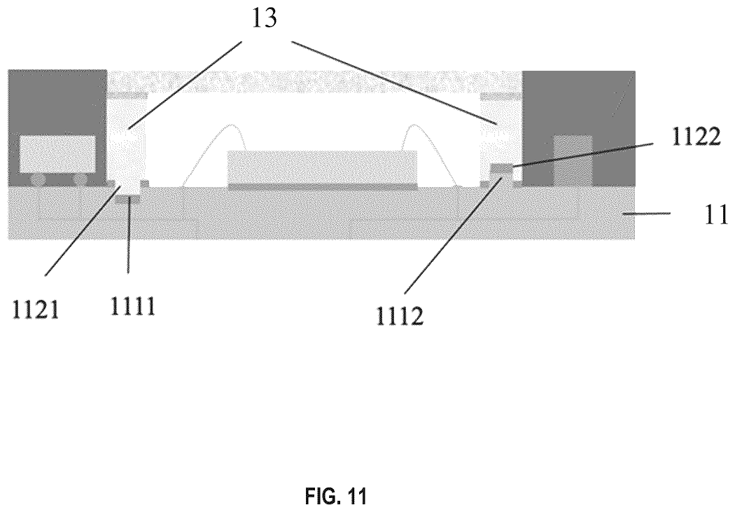

FIG. 11 is a cross-sectional schematic diagram of a partial structure of an embodiment of an optical chip packaging module;

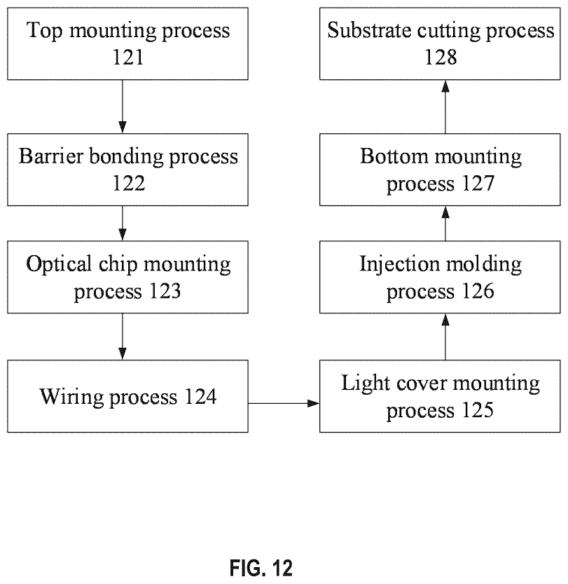

FIG. 12 is a schematic diagram of a process flow of a chip packaging process according to an embodiment; and

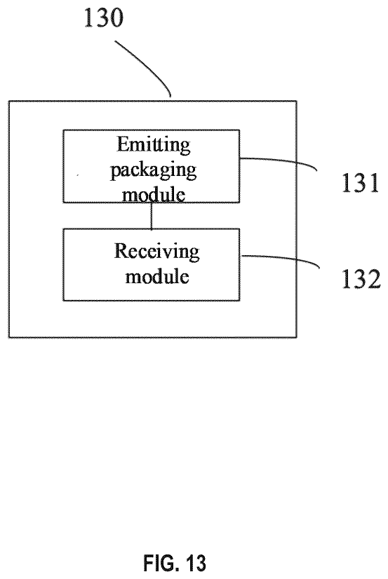

FIG. 13 is a schematic diagram of an embodiment of a LiDAR.

### DETAILED DESCRIPTION

The embodiments of the present application will be described in detail with reference to the accompanying drawings.

The singular forms of “a,” “said,” and “the” used in the specification and the appended claims are also intended to include plural forms unless the context clearly indicates other meanings. The term “and/or” used refers to and includes any or all possible combinations of one or more associated listed items.

The terms “first,” “second,” “third,” etc. may be used to describe various information, these terms are only used to distinguish the same type of information from each other. For example, the first information may be referred to as the second information, and similarly, the second information may also be referred to as the first information. Thus, the features defined as “first” and “second” may explicitly or implicitly include one or more of the features. The meaning of “multiple” is two or more, unless otherwise clearly defined.

FIG. 1 is a schematic diagram of an embodiment of the optical chip packaging module. The optical chip packaging module 10 includes a substrate 11, an optical chip 12, a barrier member 13, and a light-transmitting cover plate 14. The substrate 11 is provided with an optical region 111 and a non-optical region 112, and the optical chip 12 is fixed in the optical region 111 of the substrate 11. The barrier member 13 is fixed on the substrate 11, and is used to separate the optical region 111 from the non-optical region 112, so as to separate the optical chip 12 in the optical region 111 from a device in the non-optical region 112. The light-transmitting cover plate 14 is located above the optical region 111, and an outgoing light beam of the optical chip 12 is emitted from the light-transmitting cover plate 14. In some embodiments, no device may be placed on the light-transmitting area, or a light-transmitting cover plate 14 may be provided. In some embodiments, the barrier member 13 is used to support the light-transmitting cover plate 14, and the light-transmitting cover plate 14 and the barrier member 13 enclose a sealed cavity on the substrate 11, and the optical chip 12 is located in the sealed cavity, so that the light-transmitting cover plate 14 and the barrier member 13 are used to protect the optical chip 12. In some embodiments, the sealed cavity is also filled with an inert gas.

In some embodiments, by setting a barrier member on the substrate to divide the optical region and the non-optical region, the optical chip in the optical region and the device in the non-optical region can be effectively separated while the two regions are packaged and protected. In the optical chip packaging process, the barrier member can be first made, and then the barrier member is used as the protective boundary of the optical region for the subsequent packaging process. In this way, the barrier member can protect the optical chip in the packaging process. In the molding of the plastic packaging material and the subsequent packaging process, there is no need to perform differentiation and protection on the optical chip located in the optical region, and there is no need to use a plastic packaging cavity of a special shape, which reduces the steps of the packaging process, improves the compatibility of the plastic packaging mold, and reduces the material cost, fixture cost, and packaging process cost. Due to the setting of the barrier member, it is guaranteed that the risk of damaging the optical chip will not be introduced during the packaging operation. Moreover, since there is no medium covering the optical chip, there is no need to use a transparent medium, which reduces the packaging cost. Moreover, the cavity where the optical chip is located will be wrapped and protected by the plastic packaging material, which further enhances the cavity sealing and the mechanical strength of the package. The packaging materials used in embodiments, such as the materials of the baffles, substrates, plastic packaging, and light-transmitting cover plate (if any), do not need to be customized, which greatly reduces packaging compatibility and consumables costs.

In some embodiments, a plastic packaging material 15 is provided on at least part of the non-optical region 112 on the substrate 11, to reinforce the optical chip packaging module. The molding method of the plastic packaging material may be a process such as mold injection curing, mold compression molding or glue injection curing. In the case where no device is fixed in the non-optical region 112, the plastic packaging material 15 mainly plays a role in strengthening the stability of the overall packaging structure. In the case where a driving circuit device is fixed in the non-optical region 112, the plastic packaging material is also used to seal the device located on the non-optical region, while ensuring the stability of the sealing of the device in the non-optical region. In some embodiments, the thermal expansion coefficient of the plastic packaging material is within [11×10⁻⁶/deg, 14×10⁻⁶/deg]. In some embodiments, the thermal expansion coefficient of the plastic packaging material is similar to the thermal expansion coefficient of the substrate or the barrier member, so that the entire packaging structure has a relatively small thermal mismatch, avoiding excessive warping of the optical chip package.

In some embodiments, the barrier member 13 can be made of metal, ceramic, or plastic, or can be formed by bonding metal and plastic, or formed by resin bonding, integral injection molding, glue stripping molding, etc., which can reduce costs and process difficulties. There are many ways to fix the barrier member 13 on the substrate 11, such as bonding and fixing by bonding material 16, which can be a viscous medium such as DAF film; or fixing by metal welding.

In some embodiments, a material of the substrate 11 may include a BT substrate, a lead frame, a ceramic substrate, etc. The form of an electrical connection terminal led out of the substrate 11 includes metal pads, solder balls, etc. In some embodiments, there are many ways to fix the optical chip on the substrate, such as bonding and fixing by an adhesive material, and the adhesive material may be a viscous medium material such as silver paste, conductive glue, non-conductive glue, Film, etc., for example, fixing to each other by ball welding, sintering, etc. In some embodiments, the substrate is made of a thermally conductive material; or a thermal conductive channel is provided on the substrate in the optical region, and the optical chip is mounted on the thermal conductive channel to enable rapid heat dissipation of the optical chip.

In some embodiments, the light-transmitting cover plate 14 can be made of ordinary glass, coated glass, special glass, transparent plastic, etc. In some embodiments, the light-transmitting cover plate 14 is mounted on the top of the barrier member 13 by adhesive 18. In some embodiments, the thermal expansion coefficient of the baffle and the thermal expansion coefficient of the substrate are both within [8×10⁻⁶/deg, 12×10⁻⁶/deg]. In this way, there is a relatively small thermal mismatch between the materials of the barrier member and the substrate, which avoids the failure of the bonding delamination of the optical chip package. It can be selected whether to mount the light-transmitting cover plate 14 on the barrier member 13 according to the dustproof, waterproof, and sealing sensitivity requirements of the optical chip 12. Due to the existence of the barrier member 13, the light-transmitting cover plate 14 can form a cavity in the optical region, meet the light transmission requirements, and form a closed protective space.

In some embodiments, the optical chip 12 is used to detect a light beam. For example, the optical chip 12 includes a photoelectric sensor for converting a received optical signal into an electrical signal. In the example where the optical chip is used to detect a light beam, the optical chip packaging module is a receiving packaging module, and the optical module including the optical chip packaging module is a receiving module. The circuit structure of the receiving module including the receiving packaging module can be multiple. FIG. 2a is a schematic diagram of the logical structure of an embodiment of a receiving module. The receiving module includes a circuit board 201, as well as a power supply 202 and a charging circuit 203, both of which are arranged on the circuit board 201. In some embodiments, the receiving packaging module 204 can be arranged on a circuit board 205. The receiving packaging module 204 is electrically connected to the charging circuit 203. The power supply 202 is used to charge energy into the charging circuit 203, and the receiving packaging module 204 is powered by the charging circuit 203. In some examples, as shown in FIG. 2a, the receiving package module 204 includes an optical chip 2041 located in the optical region and a driving module 2042 of the optical chip 2041 located in the non-optical region. In some embodiments, a signal processing circuit 206 is also provided on the circuit board 205 for processing the electrical signal output by the receiving package module 204.

In some embodiments, the optical chip 12 is used to emit a light beam. The optical chip may be an emitting optical chip. For example, the optical chip 12 includes at least one group of vertical-cavity surface-emitting lasers (VCSELs). The at least one group of VCSELs is mounted to the substrate 11 by a Die Attach process, and is wire-bonded to pads on the substrate 11 to achieve electrical connection. In some embodiments, each VCSEL may be mounted to the substrate by a conductive silver glue 17. Alternatively, each VCSEL may also be soldered to the substrate by gold tin, or may be mounted to the substrate by DA (Die Attach) glue. In some embodiments, each VCSEL is distributed in an array on the substrate, and pads corresponding to the VCSELs in each row and column are bonded. In an example where the optical chip is used to emit the light beam, the optical chip packaging module is an emitting packaging module, and the optical module including the optical chip packaging module is an emitting module. The circuit structure of the emitting module including the emitting packaging module may be multiple. As shown in FIG. 2b, which is a schematic diagram of the logical structure of an embodiment of the emitting module. The emitting module includes a circuit board 21, a power supply 22, and a charging circuit 23 arranged on the circuit board 21. The emitting package module 24 can be arranged on a circuit board 25. FIG. 2b is a schematic diagram of the emitting package module 24 being arranged on a circuit board 25. The emitting package module 24 is electrically connected to the charging circuit 23. The power supply 22 is used to charge energy into the charging circuit 23, and the emitting package module 24 is powered by the charging circuit 23. In some examples, as shown in FIG. 2b, in the emitting package module 24, the optical chip 241 located in the optical region includes at least one group of lasers; a device located in the non-optical region includes an energy storage capacitor 242 and a driving module 243, and the driving module 243 is used to drive at least part of the at least one group of lasers to emit a light beam through the energy in the energy storage capacitor.

In some embodiments, the emitting package module includes an energy conversion circuit and an energy release circuit, and the energy in the energy charging circuit is transferred to the energy conversion circuit, and then transferred from the energy conversion circuit to the energy release circuit, so that at least one group of lasers emits the light beams. In some embodiments, the driving module includes a high-side driver chip located in the energy conversion circuit, and includes a low-side driver chip located in the energy release circuit. The energy conversion circuit also includes an energy storage capacitor in the emitting package module, and the energy release circuit also includes an optical chip in the emitting package module. The high-side driver chip in the energy conversion circuit is used to transfer the energy in the energy charging circuit to the energy storage capacitor, and the low-side driver chip in the energy release circuit is used to drive the energy in the energy storage capacitor to release to at least part of the lasers for emission.

In some embodiments, the optical chip includes at least two groups of VCSELs, the energy release circuit includes at least a first low-side driver chip, and the energy conversion circuit includes at least a first high-side driver chip. In some embodiments, different groups of VCSELs can emit light beams simultaneously or at different times. Each group of VCSELs includes at least one VCSEL, and each VCSEL in the same group of VCSELs can be connected in series or in parallel, so as to realize simultaneous or time-division emission of the light beams.

The first high-side driver chip and the first low-side driver chip drive the at least one group of vertical-cavity surface-emitting lasers to emit light beams by gating at least one group of the at least two groups of vertical-cavity surface-emitting lasers. In the prior art, single-sided driving (only a high-side driver chip or only a low-side driver chip) is generally used to drive a group of vertical-cavity surface-emitting lasers to emit light beams. In some embodiments, double-sided driving is used, that is, a group of VCSELs can only emit the light beams when driven by a high-side driver chip and a low-side driver chip. This can improve the flexibility of control and facilitate the selection of the VCSEL to be driven to emit a light beam from at least two groups of VCSELs when an integrated driver is used. Of course, single-sided driving can also be used.

There are many ways to connect the VCSEL, energy release circuit, energy storage capacitor, and energy conversion circuit in the emitting package module. One of them is described as an example in conjunction with FIG. 3. As shown in FIG. 3, which is a schematic diagram of the circuit topology structure of an embodiment in the emitting module. FIG. 3 is an example of each group of VCSELs containing one VCSEL. In the topological structure in FIG. 3, the charging circuit 301 includes an inductor L1 and a driving switch Q1. The energy conversion circuit 302 includes an energy storage capacitor C1, a diode switch, and at least a part of the high-side driver chip (the driving switch Q2). The energy release circuit 303 includes at least a part of the low-side driver chip (the driving switch Q3). Among them, the driving switch element can be GaN (Gallium nitride), MOSFET (Metal-Oxide-Semiconductor Field-Effect Transistor), or IGBT (Insulated Gate Bipolar Transistor), etc. In some embodiments, the driving switch is a MOSFE switch.

The power supply VCC is connected to one end of the inductor L1, and the other end of the inductor L1 is respectively connected to the source of the driving switch Q1 and the source of the driving switch Q2; the gate of the driving switch Q1 is used to receive the first pulse control signal, and the drain is grounded; the gate of the driving switch Q2 is used to receive the second pulse control signal, and the drain is connected to the anode of the diode switch D1; the cathode of the diode switch D1 is respectively connected to the positive plate of the energy storage capacitor C2 and the positive electrode of the VCSEL 31; the cathode of the VCSEL 31 is connected to one electrode of the driving switch Q3, the cathode plate of the energy storage capacitor C2 is grounded, the drain of the other two electrodes of the driving switch Q3 is grounded, and the gate is used to receive the third pulse control signal.

There are multiple working modes for the circuit topology shown in FIG. 3. In an example, VCSEL 31 periodically emits pulsed light beam. Before the VCSEL emits pulsed light beam in each period, the driving switches Q2 and Q3 are in the off state, and the first pulse control signal is used to turn on the driving switch Q1, so that the charging circuit of the power supply VCC-inductor L1-driving switch Q1 is turned on, so that the power supply VCC charges the inductor L1. After the inductor L1 is charged, the first pulse control signal is used to turn off the transistor switch Q1, and the second pulse control signal is used to turn on the driving switch Q2, so that the energy conversion circuit of the inductor L1-driving switch Q2-diode switch D1-energy storage capacitor C1 is turned on, and then the energy of the inductor L1 is stored in the energy storage capacitor C1 in the emitting package module. After storage is completed, the driving switch Q2 is turned off, and the third pulse control signal is used to turn on the driving switch Q3, so that the energy release circuit of the energy storage capacitor C1-VCSEL 31-driving switch Q3 is turned on, and then the energy in the energy storage capacitor C1 is released to VCSEL 31, so that VCSEL 31 emits a light beam.

In some examples, the emitting package module includes x anode driving modules and y cathode driving modules, the emitting package module includes p energy storage capacitors, and n groups of VCSELs, the x anode driving modules correspond to the p energy storage capacitors, p is a positive integer greater than or equal to one and less than or equal to n, x is a positive integer less than or equal to p, where each anode driving module corresponds to at least one energy storage capacitor, and each anode driving module corresponds to different energy storage capacitors; the y cathode driving modules correspond to n groups of VCSELs, where each cathode driving module corresponds to at least one group of VCSELs, and each cathode driving module corresponds to different groups of VCSELs; where n is a positive integer greater than one, and y is a positive integer less than or equal to n. Each anode driving module may include a driving switch Q2 and/or a diode switch D1 as shown in FIG. 3, and each cathode driving module may include a driving switch Q3 as shown in FIG. 3. Each high-side driver chip includes at least part of the x anode driving modules, and each low-side driver chip includes at least part of the y cathode driving modules. In an example where only one high-side driver chip and one low-side driver chip are provided in the emitting package module, the high-side driver chip includes the x anode driving modules, and the low-side driver chip includes the y cathode driving modules. In an example where two high-side driver chips and two low-side driver chips are provided in the emitting package module, one of the two high-side driver chips includes a portion of the x anode driving modules, and the other includes the remaining portion of the x anode driving modules; one of the two low-side driver chips includes a portion of the y cathode driving modules, and the other includes the remaining portion of the y cathode driving modules.

The n groups of VCSELs can be used to emit light beams at the same time, or the emission times are staggered, and divided into n times to emit light beams in sequence. Before each group of VCSELs in the n groups of VCSELs emit the light beams, the anode driving module corresponding to the group of VCSELs emitting the light beam is used to transfer the energy in the charging circuit to the corresponding energy storage capacitor, and the corresponding cathode driving module is used to release the energy in the corresponding energy storage capacitor to the group of VCSELs, so that the group of VCSELs emits the light beams. In some embodiments, the emitting module may also include m power supplies and q charging circuits (where m≤q, and m is an integer greater than or equal to one), respectively corresponding to the p energy storage capacitors in the emitting package module, and the p energy storage capacitors correspond to the n groups of VCSELs. When m is less than q, at least in some of the power supplies, each power supply corresponds to no less than two charging circuits. When q is less than p, at least in part of the charging circuits, each charging circuit corresponds to no less than two energy storage capacitors. When p is less than n, at least in part of the energy storage capacitors, each energy storage capacitor corresponds to no less than two groups of VCSELs. Before at least one group of VCSELs emits the light beams, the power supply corresponding to the group of VCSELs is used to charge energy into the corresponding energy charging circuit, and the corresponding energy conversion circuit is used to transfer the energy in the corresponding energy charging circuit to the energy storage capacitor corresponding to the group of VCSELs before the group of VCSELs emits the light beams.

The voltage values of the m power supplies can be equal or unequal. In some embodiments, the m groups of power supplies can also drive different numbers of energy conversion circuits. The power supply corresponding to the middle area of the detection field of view can drive fewer groups of energy release circuits, and the power supply corresponding to the edge area of the detection field of view can drive more groups of potential energy circuits. For example, the power supply in the middle area drives a group of energy release circuits, and the power supply in the edge area drives b group of energy release circuits, then a≤b. By controlling the voltage values of the m power supplies and the number of energy release circuits in the transmitting array in the detection field of view corresponding to the m power supplies, the detection requirements can be further matched on the basis of the emitting module to achieve detection flexibility.

As shown in FIG. 3, a group of VCSELs in the topological structure shown in FIG. 3 is an emission channel, and FIG. 3 illustrates a 4*4 group of VCSEL arrays, where each group of VCSELs includes one VCSEL. FIG. 3 shows the circuit loop corresponding to a group of VCSELs 31: power supply, charging circuit, and emitting packaging module. In some embodiments, the circuit loops of the remaining groups of VCSELs in the 4*4 group of VCSEL array except the first group of VCSELs 31 can be as shown in the circuit loop of the first group of VCSELs 31, which is not shown in FIG. 3 to simplify FIG. 3.

In some embodiments, the at least two groups of VCSELs are VCSEL arrays arranged in a rectangular array, and each group of VCSELs is an element in the VCSEL array; the first high-side driver chip is used to drive at least one row of elements selected in the VCSEL array; and the first low-side driver chip is used to drive at least one column of elements selected in the VCSEL array. Then only a group of VCSELs located in a row selected by the first high-side driver chip and a column selected by the first low-side driver chip will be driven successfully to emit a light beam. In this way, the VCSEL to be driven is selected by gating rows and columns, which can improve the flexibility of control. In some embodiments, the at least two groups of VCSELs can be arranged in arrays of other shapes, such as a circular array, an elliptical array, etc. The driving module can also drive different groups of VCSELs separately. A group of VCSELs includes at least one VCSEL. In some embodiments, a group of VCSELs includes multiple VCSEL emitters, such as 2, 3, 8, 9, etc.

In an example, at least two groups of VCSELs and their driving modules and energy storage capacitors are partially packaged and systemized into an emitting package module. During assembly, the packaged emitting package module can be mounted on the circuit board; compared with the prior art in which multiple VCSELs and their driving modules and energy storage capacitors are directly mounted on the circuit board, once a scrapped VCSEL appears, the circuit board of the entire product will be scrapped. The embodiment can better screen the emitting package module in advance to achieve a higher yield control. The embodiment can reduce the process difficulty. In existing products, each VCSEL is often required to align and fit on the circuit board with high precision. In some embodiments, the emitting package module is formed by pre-packaging, which can reduce the difficulty of packaging each VCSEL on the circuit board. Each VCSEL and its energy storage capacitor and driving module are packaged in the emitting package module, which can reduce the parasitic parameters in the control driving circuit. Moreover, by integrating the key device modules in the emitting module and packaging them as a whole, this form can ensure the consistency and stability of the multi-channel emitting device, and the internal environment is stable through the sealed package structure, thereby improving the reliability of the core power device and the driver device, and improving the reliability of the overall emitting module. The reliability requirements of vehicle-mounted devices are very high, and the devices are usually subjected to WHTOL testing. The test environment is usually a high temperature and high humidity environment. For unpackaged device bare dies, water molecules or impurities will usually penetrate at the edge of the device or the relatively weak position of the protective layer. After a long period of electromigration effect, it is easy to cause internal conduction or open circuit failure of the device. In some embodiments, the VCSEL and its driving module and energy storage capacitor are partially packaged and systematized into the emitting packaging module and then fixed to the circuit board of the emitting module, so that the emitting module is easier to meet the reliability requirements of vehicle-mounted devices.

As shown in FIG. 4, which is a schematic diagram of a circuit topology structure of an embodiment of the emitting package module. In the topology structure shown in FIG. 4, the energy conversion circuit 402 further includes driving switches Q4 and Q5, which are used to release the energy stored in the parasitic capacitors on each driving switch in the circuit, after the energy storage capacitor C1 transfers the energy to at least one group of VCSELs in the VCSEL array.

In some embodiments, the emitting package module includes at least one bootstrap capacitor for opening or maintaining the driving state of the first high-side driver chip. For example, as shown in FIG. 4, the energy conversion circuit 402 includes at least one bootstrap capacitor C2 for connecting to at least one end of the first high-side driver chip, for opening or maintaining the driving state of the connected high-side driving switch. In some embodiments, on the substrate of the emitting package module, the at least one bootstrap capacitor and the pins of the first high-side driver chip are arranged adjacent to each other.

In some embodiments, the emitting package module further includes at least one decoupling capacitor corresponding to the at least one high-side driver chip and/or the at least one low-side driver chip. At least one high-side driver chip and/or at least one low-side driver chip in the emitting package module are respectively connected to the negative electrode of the power supply (or ground) through the at least one decoupling capacitor. For example, all high-side driver chips are connected to the negative electrode of the power supply (or ground) through one decoupling capacitor, and all low-side driver chips are connected to the negative electrode of the power supply (or ground) through another decoupling capacitor; or, all high-side and low-side driver chips are connected to the negative electrode of the power supply (or ground) through the same decoupling capacitor; or, each high-side driver chip is connected to the negative electrode of the power supply (or ground) through a different decoupling capacitor, and each low-side driver chip is connected to the negative electrode of the power supply (or ground) through a different decoupling capacitor. As shown in FIG. 4, all anode driving switches in the energy conversion circuit 402 are connected to the power supply through the first decoupling capacitor C3, and all cathode driving switches in the energy release circuit 404 are connected to the negative electrode of the power supply (or ground) through the second decoupling capacitor C4. The first decoupling capacitor C3 and the second decoupling capacitor C4 are both located on the non-optical region of the substrate.

Generally, the working voltages of the high-side driver chip and the low-side driver chip are fixed at certain voltage values, respectively. The power supply first passes through the decoupling capacitor and then supplies power to the high-side driver chip and the low-side driver chip, which can prevent the parasitic oscillation caused by the positive feedback path formed by the circuit through the power supply VCC, that is, to prevent the current fluctuation formed in the power supply circuit from affecting the normal operation of the circuit when the circuit current changes, so that the parasitic coupling between the circuits can be effectively eliminated to ensure the relative stability of the power supply. In some embodiments, the pins of the at least first high-side driver chip and/or the at least first low-side driver chip are adjacent to the corresponding decoupling capacitors.

As shown in FIG. 5, which is a schematic diagram of an embodiment of the arrangement of at least some components in the emitting packaging module. At least two groups of VCSELs in the emitting packaging module are arranged in an array. A first high-side driver chip 511 and a first low-side driver chip 512 are located around the VCSEL array 510. In some embodiments, the emitting packaging module also includes a second high-side driver chip 513, which is located on opposite sides of the VCSEL array with the first high-side driver chip 511, respectively, and is used to drive lasers in different regions of the VCSEL array. For example, as shown in FIG. 5, the driving module includes a first high-side driver chip 511 located on the left side of the VCSEL array, and a second high-side driver chip 513 located on the right side of the VCSEL array. The VCSEL array is divided into two different regions, which are driven by the first high-side driver chip 511 and the second high-side driver chip 513, respectively. For example, the first high-side driver chip 511 is used to drive each group of VCSELs in the odd-numbered rows of the VCSEL array 510, and the second high-side driver chip 513 is used to drive each group of VCSELs in the even-numbered rows of the VCSEL array 510. For an example, the first high-side driver chip 511 is used to drive each group of VCSELs in the upper half of the VCSEL array 510, and the second high-side driver chip 513 is used to drive each group of VCSELs in the lower half of the VCSEL array 510. In the case where the number of columns of the VCSEL array is large, high-side driver chips are respectively arranged on both sides of the VCSEL array, which can reduce the distance between the VCSELs and the high-side driver chip, improve the response speed of the VCSELs, and reduce circuit loss.

In some embodiments, the driving module further includes a second low-side driver chip 514, and a first low-side driver chip 512 are respectively located on opposite sides of the VCSEL array, and are respectively used to drive lasers in different regions of the VCSEL array. For example, as shown in FIG. 5, the driving module includes a first low-side driver chip 512 located on one side of the upper side of the VCSEL array 510, and a second low-side driver chip 514 located on one side of the lower side of the VCSEL array 510. The first low-side driver chip 512 is used to drive each group of VCSELs in the right region of the VCSEL array 510 close to the first high-side driver chip 511. The second low-side driver chip 514 is used to drive each group of VCSELs in the left region of the VCSEL array 510 close to the second high-side driver chip 513. In the case where the number of rows of the VCSEL array is large, the low-side driver chips are arranged on both sides of the VCSEL array, which can reduce the distance between the VCSELs and the low-side driver chip, improve the response speed of the VCSELs, and reduce the circuit loss, thereby avoiding the situation where the laser output power does not meet the requirements.

A barrier member 516 is arranged between the VCSEL array 510 and the first high-side driver chip 511, the second high-side driver chip 513, the first low-side driver chip 512, and the second low-side driver chip 514. The barrier member 516 is used to enclose the region between them into an optical region, and the VCSEL array 510 is arranged in the enclosed optical region.

The example of two high-side driver chips and/or two low-side driver chips can simultaneously drive more groups of VCSELs to emit light beams, which is convenient for selecting the number of VCSELs that emit light beams simultaneously according to detection requirements, thereby further improving the flexibility of detection. The emitting package module includes two high-side driver chips and one low-side driver chip. In some embodiments, the two high-side driver chips can drive each group of VCSELs in different rows, and the one low-side driver chip can drive each group of VCSELs in all columns. Alternatively, the emitting package module includes one high-side driver chip and two low-side driver chips. In some embodiments, the one high-side driver chip can drive each group of VCSELs in all rows, and the two low-side driver chips can drive each group of VCSELs in different columns.

In some embodiments, as shown in FIG. 5, the emitting package module includes an energy storage capacitor array 517, which is arranged in two columns and is respectively located on both sides of the VCSEL array 510, and the barrier member 515 and 516 are respectively located between the two columns of energy storage capacitors and the VCSEL array 510 to block the energy storage capacitor array 517 outside the optical region. In some embodiments, each column of energy storage capacitors is located between the VCSEL array 510 and the driver chip. In some embodiments, each column of energy storage capacitors is located between the VCSEL array 510 and the high-side driver chip. By placing the energy storage capacitor close to the VCSEL and reducing the distance between the energy storage capacitor and the corresponding VCSEL, the parasitic parameters on the path between the energy storage capacitor and the corresponding VCSEL can be reduced, and more energy can be transferred to the VCSEL.

FIG. 6 is a schematic diagram of an embodiment of the arrangement of at least some components in the emitting packaging module. On the substrate, the barrier member 66 encloses a rectangular region (the optical region) and encloses the VCSEL array 60 therein. The barrier member 66 can be an integrally formed structural member to further ensure the airtightness of the optical region of the package. In some embodiments, the barrier member 66 can be a combination of multiple structural members to form a closed space. Outside the barrier member 66, a column of energy storage capacitors 61 is arranged on the left and right sides of the VCSEL array 60.

A low-side driver chip 65 is disposed on the upper and lower sides of the VCSEL array 60. The pins of the low-side driver chip 65 are arranged along the side of the low-side driver chip 65 facing away from the VCSEL array 60, and the decoupling capacitors corresponding to the low-side driver chip 65 are arranged along the side of the low-side driver chip 65 facing away from the VCSEL array 60, so as to be disposed adjacent to the pins of the low-side driver chip 65.

A high-side driver chip 62 is provided on the side of each column of energy storage capacitors 61 facing away from the VCSEL array 60, and the pins of the high-side driver chip 62 are arranged along the side of the high-side driver chip 62 facing away from the energy storage capacitor 61, and the bootstrap capacitors 63 corresponding to the high-side driver chip 62 are arranged along the side of the high-side driver chip 62 facing away from the energy storage capacitor 61, so as to be arranged adjacent to the pins of the high-side driver chip 62. In some embodiments, a decoupling capacitor corresponding to the high-side driver chip 62 is provided on the side of the substrate facing away from the VCSEL array 60, and is arranged adjacent to the pins of the high-side driver chip 62.

In both FIG. 5 and FIG. 6, the energy storage capacitor is located between the VCSEL array and the high-side driver chip for example. In some embodiments, the energy storage capacitor may be located between the VCSEL array and the low-side driver chip. In some embodiments, the energy storage capacitor and the low-side driver chip are both located in the non-optical region.

In some embodiments, each capacitor in the emitting package module (e.g., energy storage capacitor, decoupling capacitor, bootstrap capacitor) can be mounted to the substrate by surface mount technology (SMT). In some embodiments, each capacitor can be connected to the corresponding VCSEL by a lead.

In some embodiments, the high-side driver chip can be pre-packaged through a chip scale package (CSP) process. CSP is a standard type of packaging that does not involve specific packaging technology. The ratio of the core area to the package area in the CSP package is about 1:1.1. There are many CSP packaging technologies, such as WLCSP, uBGA, WBGA, TinyBGA, FBGA, and other small chip packaging technologies. When the components are mounted on the substrate through the COP process, the wire bonding form requires a large number of bonding, the processing is low, and the integration is poor. In this example, the high-side driver chip is pre-packaged through the WLCSP process, which is conducive to simplifying the process of the overall SIP (system in package) packaging and improving the integration. In some embodiments, the high-side driver chip is pre-packaged into a ball grid array (BGA) package form through the WLCSP process, and is mounted on the non-optical region of the substrate through the ball pins.

In some embodiments, the high-side driver chip is mounted on the non-optical region of the substrate by a flip chip process or a surface mount (SMT) process. In this process, the front side of the high-side driver chip is mounted on the substrate with the front side facing the substrate. In some embodiments, the high-side driver chip can also be mounted on the substrate by a COB process and then wire-bonded to the pads on the substrate.

FIG. 7 is a cross-sectional schematic diagram of a partial structure of an embodiment of an optical chip packaging module. In some embodiments, four barrier member 72 are provided on the substrate 71, and the region enclosed by the four barrier member 72 is the optical region on the substrate, and the region outside the enclosed region is the non-optical region. The optical chip 73 is provided in the optical region. In some embodiments, a low-side driver chip is also fixed outside the optical region, located on the upper and lower sides of the optical region.

The two high-side driver chips 74 are pre-packaged in a BGA package form through the WLCSP process, and are mounted on the non-optical region of the substrate through ball pins 741, and are respectively located on the left and right sides of the optical chip 73. In some embodiments, the optical chip packaging module can be packaged in a BGA package form and mounted on the circuit board through the ball pins 75. In the non-optical regions on the left and right sides of the optical chip 73, a row of energy storage capacitors 76 and a row of bootstrap capacitors 77 are also fixed on the non-optical regions on each side. Each component on the non-optical region is plastic-sealed in a plastic packaging material 78. In some embodiments, the optical chip packaging module includes a light-transmitting cover plate 79, which is supported on the barrier member 72 and enclosed with each barrier member 72 on the substrate to form a sealed cavity. In some embodiments, a step structure 791 is provided on the periphery of the light-transmitting cover plate 79, and the plastic packaging material 78 extends above the step structure 791 to press the light-transmitting cover plate 79 toward the barrier member 72. This can prevent the light-transmitting cover plate from falling off.

In some examples, a structure on the light-transmitting cover plate used to fix the plastic packaging material to each other may not be a step structure provided on the periphery of the light-transmitting cover plate, but a structure of other shapes. For example, as shown in FIG. 8, which is a cross-sectional schematic diagram of a partial structure of an embodiment of an optical chip packaging module, a step structure 811 is provided on the periphery of the light-transmitting cover plate 81, and the plastic packaging material 82 extends above the step structure 811 to press the light-transmitting cover plate 81 against the barrier member 83 to form a structure for locking the light-transmitting cover plate 81 to enhance the sealing of the cavity and improve reliability.

In some examples, the plastic packaging material may not need to extend to cover the edge of the light-transmitting cover plate, but as in the embodiment shown in FIG. 1, the side of the plastic packaging material and the periphery of the light-transmitting cover plate are in contact. Alternatively, in some examples, the periphery of the light-transmitting cover plate extends to press on the plastic packaging material. FIG. 9 is a cross-sectional schematic diagram of a partial structure of an embodiment of an optical chip packaging module. The barrier member 91 and the plastic packaging material 92 are arranged side by side. The light-transmitting cover plate 93 is supported on the barrier member, and the periphery of the light-transmitting cover plate 93 extends to cover part or all of the plastic packaging material 92, and is fixed to the plastic packaging material 92 by adhesive. In the example shown in FIG. 9, the periphery of the light-transmitting cover plate 93 only covers part of the plastic packaging material 92.

FIG. 10 is a cross-sectional schematic diagram of a partial structure of an embodiment of the optical chip packaging module. In some embodiments, a limiting step 1011 is provided on the top of the barrier member 101 to match the light-transmitting cover plate 102, and is used to match the periphery of the light-transmitting cover plate 102. The light-transmitting cover plate 102 is stuck in the limiting step 1011, and the periphery is in contact with the inner surface of the limiting step 1011, and the light-transmitting cover plate 102 is limited by the limiting step 1011.

In some examples, in addition to glue, the substrate and the barrier member can be fixed to each other through structural cooperation. FIG. 11 is a cross-sectional schematic diagram of a partial structure of an embodiment of an optical chip packaging module. A limit groove 1111 is provided on the substrate 11, which is used to cooperate with the protrusion 1121 at the bottom of the barrier member 13 to fix the barrier member 13. In some embodiments, a limit groove 722 is provided at the bottom of the barrier member 13, which is used to cooperate with the protrusion 1112 on the substrate 11 to fix the barrier member 13. In some embodiments, glue is also applied to the bottom of the limit groove 1111 or the limit groove 1122 to bond the substrate 11 and the barrier member 13.

There are many ways to package the optical chip packaging module. The chip packaging process in some embodiments is described by way of example in combination with the embodiment shown in FIG. 7. In an example, as shown in FIG. 12, which is a flow chart of an embodiment of the chip packaging process, the packaging process of the emitting packaging module includes a top mounting process 121, a barrier bonding process 122, an optical chip mounting process 123, a wiring process 124, a light cover mounting process 125, an injection molding process 126, a bottom mounting process 127, and a substrate cutting process 128.

In the top mounting process 121, the electrical components and chips (such as the high-side driver chip 74, the energy storage capacitor 76, the bootstrap capacitor 77, etc.) on the upper side of the substrate are fixed to the upper side of the substrate through the surface mounting technology (SMT) process and are electrically connected to the substrate. If the high-side driver chip requires underfill, the high-side driver chip is underfilled after SMT; if the ball gap of the high-side driver chip 74 is large, it can support the filling of the plastic encapsulation material in the molding process during the injection molding process, and the underfill step can be omitted.

In the barrier bonding process 122, the barrier member is bonded to the substrate using the same process as the Die Attach process, so that the optical region and the non-optical region on the substrate are divided by the barrier member. This step can be completed before the optical cover mounting process 125.

In the optical chip mounting process 123, the optical chip is attached to the substrate using a Die Attach process.

In the wiring process 124, the Wire Bond process is used to electrically connect the optical chip and the chip that needs to be connected to the substrate through wire bonding to the substrate through gold wires.

In the optical cover mounting process 125, for the chip that needs a light-transmitting cover plate, the same process as Die Attach is used to apply adhesive material on the upper side of the barrier member, and the light-transmitting cover plate and the barrier member are bonded and fixed, so that the optical region where the optical chip is located forms a closed cavity and meets the light transmission requirements.

In the injection molding process 126, the non-optical region is protected by a plastic encapsulation process. In this step, the barrier member provides physical protection for the optical region, ensuring that the optical region is not filled with the plastic encapsulation material.

In the bottom mounting process 127, the electrical components under the substrate are fixed to the bottom of the substrate through the SMT process and are electrically connected to the substrate. For substrates that require bottom ball planting, this step simultaneously completes the connection between the ball pins 75 and the substrate.

In the substrate cutting process 128, the strip-shaped substrate is cut into individual chips to complete the packaging.

Some embodiments of the present application provide a LiDAR, including an optical chip packaging module, which may be an optical chip packaging module described in any of the above items. FIG. 13 is a schematic diagram of an embodiment of the LiDAR. The LiDAR 130 includes the above-described emitting optical chip packaging module 131 for emitting the light beams. In some embodiments, the LiDAR also includes a receiving optical chip packaging module 132 for receiving the echo light beams. In some embodiments, the LiDAR may be a solid-state LiDAR. The LiDAR may also include a scanning device to achieve detection in a wider range. The scanning device may be, for example, a galvanometer, a rotating mirror, or a driving platform. The scanning device may be a combination of one or more of the above-mentioned driving devices. For example, the scanning device may be a combination of a galvanometer and a rotating mirror, and in some embodiments the scanning device may also be a galvanometer, or the scanning device may be a rotating mirror, or the scanning device may be a driving platform. The LiDAR may only include the emitting optical chip packaging module in the above packaging form, or may only include the receiving optical chip packaging module in the above packaging form, or may include both the emitting optical chip packaging module and the receiving optical chip packaging module. Of course, the optical chip packaging module can be used in infrared detectors, projector light sources, or 3D ToF (Time of Flight) modules of mobile phones.

What is claimed is:

1. An optical chip packaging module, comprising:
a substrate, provided with an optical region and a non-optical region;
an optical chip, fixed to the optical region of the substrate; and
a barrier member, fixed on the substrate and configured to separate the optical region from the non-optical region, so as to separate the optical chip in the optical region from a device in the non-optical region; and
a light-transmitting area, located above the optical region, wherein an outgoing light beam of the optical chip is emitted from the light-transmitting area.

2. The optical chip packaging module according to claim 1, wherein
a limit groove is provided on the substrate, and the limit groove is configured to cooperate with a protrusion at a bottom of the barrier member to fix the barrier member; or
a limit groove is arranged at the bottom of the barrier member, and the limit groove is configured to cooperate with a protrusion on a base plate to fix the barrier member.

3. The optical chip packaging module according to claim 1, wherein
a light-transmitting cover plate is disposed on the substrate;
the barrier member is used to support the light-transmitting cover plate; and
the light-transmitting cover plate and the barrier member are enclosed on the substrate to form a sealed cavity,
wherein the optical chip is located in the sealed cavity.

4. The optical chip packaging module according to claim 3, wherein a limiting step cooperating with the light-transmitting cover plate is provided on the top of the barrier member, and configured to match with a periphery of the light-transmitting cover plate, to limit the light-transmitting cover plate.

5. The optical chip packaging module according to claim 1, wherein the substrate is made of a thermally conductive material; or
a heat conduction channel is provided on the substrate in the optical region, and the optical chip is mounted on the heat conduction channel.

6. The optical chip packaging module according to claim 1, wherein a plastic packaging material is provided on at least part of the non-optical region on the substrate, to reinforce the optical chip packaging module.

7. The optical chip packaging module according to claim 6, wherein the plastic packaging material is used to seal the device located on the non-optical region.

8. The optical chip packaging module according to claim 6, wherein the plastic packaging material extends to a periphery of a light-transmitting cover plate, to press the light-transmitting cover plate toward a top of the barrier member.

9. The optical chip packaging module according to claim 8, wherein the periphery of the light-transmitting cover plate has a slope structure or a step structure, and the plastic packaging material extends onto the slope structure or the step structure.

10. An optical module, comprising an optical chip packaging module and a circuit board;
the circuit board is provided with a power supply and a charging circuit; and
the circuit board is electrically connected to the optical chip packaging module,
wherein the optical chip packaging module comprises:
a substrate, provided with an optical region and a non-optical region;
an optical chip, fixed to the optical region of the substrate; and
a barrier member, fixed on the substrate and configured to separate the optical region from the non-optical region, so as to separate the optical chip in the optical region from a device in the non-optical region; and
a light-transmitting area, located above the optical region, wherein an outgoing light beam of the optical chip is emitted from the light-transmitting area.
